(19) United States
(12) Patent Application Publication
(10) Pub. No.: US 2025/0194373 A1
(43) Pub. Date: Jun. 12, 2025

(54) DISPLAY DEVICE AND ELECTRONIC DEVICE INCLUDING THE SAME

(71) Applicant: Samsung Display Co., LTD., Yongin-si (KR)

(72) Inventors: YOUNGSANG YOON, Yongin-si (KR); JE HYEONG PARK, Yongin-si (KR); HYUN-CHUL PARK, Yongin-si (KR); KIWAN AHN, Yongin-si (KR); BEOMHEE HAN, Yongin-si (KR)

(21) Appl. No.: 18/972,527

(22) Filed: Dec. 6, 2024

(30) Foreign Application Priority Data
Dec. 8, 2023 (KR) 10-2023-0177388

(51) Int. Cl. H10K 59/38; H10K 59/122; H10K 59/127; H10K 102/00

(52) U.S. Cl. CPC H10K 59/38; H10K 59/127; H10K 59/122; H10K 2102/331; H10K 2102/351

(57) ABSTRACT

A display device includes a base substrate including a display area, a first area adjacent to the display area, a sealing area adjacent to the first area, and a second area adjacent to the sealing area, a second base substrate facing the first base substrate, a first light emitting element disposed on the first base substrate and partially overlapping the display area, a second light emitting element disposed on the first base substrate, partially overlapping the display area, and spaced apart from the first light emitting element, a sealing member disposed between the first base substrate and the second base substrate and overlapping the sealing area, a color filter layer disposed between the second base substrate and the sealing member and defining a first cutout portion partially overlapping the second area and a low refractive index layer disposed under the color filter layer and filling the first cutout portion.

This application claims priority to Korean Patent Application No. 10-2023-0177388, filed on Dec. 8, 2023, and all the benefits accruing therefrom under 35 U.S.C. § 119, the content of which in its entirety is herein incorporated by reference.

### BACKGROUND

### 1. Technical Field

Embodiments relate generally to a display device and an electronic device including the display device, and more particularly to a display device having an improved display quality and an electronic device including the display device.

### 2. Description of the Related Art

A display device is a device that displays an image for providing visual information to a user. Among display devices, an organic light emitting diode display has recently attracted attention.

Recently, in order to improve display quality, a display device including a display unit including a plurality of pixels and a color filter unit including a color filter layer and a color converting layer has been proposed. A low refractive index layer may be disposed under the color filter layer. The low refractive index layer may increase light extraction efficiency to increase luminance and lifespan of the display device.

### SUMMARY

Embodiments provide a display device with improved display quality.

Embodiments provide an electronic device including the display device.

A display device, according to an embodiment, includes a base substrate including a display area, a first area disposed adjacent to the display area, a sealing area disposed adjacent to the first area, and a second area disposed adjacent to the sealing area, a second base substrate facing the first base substrate, a first light emitting element disposed on the first base substrate and partially overlapping the display area, a second light emitting element disposed on the first base substrate, partially overlapping the display area, and spaced apart from the first light emitting element, a sealing member disposed between the first base substrate and the second base substrate and overlapping the sealing area, a color filter layer disposed between the second base substrate and the sealing member, including a first color filter, a second color filter, and a third color filter, and defining a first cutout portion partially overlapping the second area, and a low refractive index layer disposed under the color filter layer and filling the first cutout portion.

In an embodiment, the second color filter may be disposed on the first color filter and the third color filter may be disposed on the second color filter.

In an embodiment, the first cutout portion may be a portion from which the first color filter is removed.

In an embodiment, the first cutout portion may be a portion from which the first color filter and the second color filter are removed.

In an embodiment, the color filter layer may further define a second cutout portion spaced apart from the first cutout portion and partially overlapping the second area.

In an embodiment, the second cutout portion may be a portion from which the first color filter is removed.

In an embodiment, the second cutout portion may be a portion from which the first color filter and the second color filter are removed.

In an embodiment, the low refractive index layer may fill the second cutout portion.

In an embodiment, the second area may include a first cutout area overlapping the first cutout portion, a second cutout area overlapping the second cutout portion, a first intermediate area disposed between the first cutout area and the second cutout area, and a second intermediate area disposed adjacent to the second cutout area and spaced apart from the first intermediate area.

In an embodiment, a thickness of the low refractive index layer overlapping the sealing area may be greater than a thickness of the low refractive index layer overlapping the first intermediate area.

In an embodiment, the thickness of the low refractive index layer overlapping the sealing area may be smaller than a thickness of the low refractive index layer overlapping the first cutout area.

In an embodiment, the thickness of the low refractive index layer overlapping the sealing area may be greater than a thickness of the low refractive index layer overlapping the second intermediate area.

In an embodiment, the display device may further include a bank layer disposed between the color filter layer and the first base substrate and defining a first opening overlapping the first light emitting element and a second opening overlapping the second light emitting element.

In an embodiment, the display device may further include a color converting layer filling the first opening and including a first scattering body and a first wavelength converting particle.

In an embodiment, the display device may further include the transmitting layer filling the second opening and including the second scattering body.

In an embodiment, the bank layer may overlap the first area and the sealing area and may partially overlap the second area.

A display device, according to another embodiment, includes a base substrate including a display area, a first area disposed adjacent to the display area, a sealing area disposed adjacent to the first area, and a second area disposed adjacent to the sealing area, a second base substrate facing the first base substrate, a first light emitting element disposed on the first base substrate and partially overlapping the display area, a second light emitting element disposed on the first base substrate, partially overlapping the display area, and spaced apart from the first light emitting element, a sealing member disposed between the first base substrate and the second base substrate and overlapping the sealing area, a color filter layer disposed between the second base substrate and the sealing member, partially overlapping the second area, overlapping the sealing area and the first area, and including a first color filter, a second color filter disposed on the first color filter, and a third color filter disposed on the second color filter, and a low refractive index layer disposed under the color filter layer.

In an embodiment, a distance between an end of the second color filter and the sealing area may be greater than a distance between an end of the first color filter and the sealing area.

In an embodiment, a distance between an end of the third color filter and the sealing area may be greater than the distance between the end of the second color filter and the sealing area.

In an embodiment, the third color filter may completely overlap the second area.

In an embodiment, a thickness of the low refractive index layer overlapping the sealing area may be greater than a thickness of each of the low refractive index layer overlapping the end of the first color filter, the low refractive index layer overlapping the end of the second color filter, and the low refractive index layer overlapping the end of the third color filter.

In an embodiment, the display device may further include a bank layer disposed between the color filter layer and the sealing member and overlapping the first area, the second area, and the sealing area.

An electronic device, according to an embodiment, includes a base substrate including a display area, a first area disposed adjacent to the display area, a sealing area disposed adjacent to the first area, and a second area disposed adjacent to the sealing area, a second base substrate facing the first base substrate, a first light emitting element disposed on the first base substrate and partially overlapping the display area, a second light emitting element disposed on the first base substrate, partially overlapping the display area, and spaced apart from the first light emitting element, a sealing member disposed between the first base substrate and the second base substrate and overlapping the sealing area, a color filter layer disposed between the second base substrate and the sealing member, including a first color filter, a second color filter, and a third color filter, and defining a first cutout portion partially overlapping the second area, a low refractive index layer disposed under the color filter layer and filling the first cutout portion, and a memory device configured to store data.

A display device, according to an embodiment, may include a color filter layer. The color filter layer may include a first color filter, a second color filter disposed on the first color filter, and a third color filter disposed on the second color filter. The color filter layer may define a first cutout portion and a second cutout portion in a non-display area. A low refractive index layer may fill each of the first cutout portion and the second cutout portion.

In an embodiment, a thickness of the low refractive index layer may be reduced in the non-display area. Accordingly, an area of the low refractive index layer through which moisture and oxygen may penetrate may be minimized. Accordingly, occurrence of dark spots, bank layer lifts, and the like, may be minimized.

A display device, according to another embodiment, may include a color filter layer. In addition, the display device may include a display area, a first area disposed adjacent to the display area, a sealing area disposed adjacent to the first area, and a second area disposed adjacent to the sealing area.

In an embodiment, the color filter layer may include a first color filter, a second color filter disposed on the first color filter, and a third color filter disposed on the second color filter. A distance between an end of the second color filter and the sealing area may be greater than a distance between an end of the first color filter and the sealing area. In addition, a distance between an end of the third color filter and the sealing area may be greater than a distance between the end of the second color filter and the sealing area. A low refractive index layer may be disposed under the color filter layer.

In an embodiment, a thickness of the low refractive index layer overlapping the end of each of the first color filter, the second color filter, and the third color filter may be reduced. Accordingly, an area of the low refractive index layer through which moisture and oxygen may penetrate may be minimized. Accordingly, occurrence of dark spots, bank layer lifts, and the like, may be minimized.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device, according to an embodiment.

FIG. 2 is a cross-sectional view of the display device of FIG. 1 taken along line I-I′, according to an embodiment.

FIG. 3 is a cross-sectional view illustrating an example of a non-display area of the display device of FIG. 2, according to an embodiment.

FIG. 4 is a plan view illustrating the display device of FIG. 1, according to an embodiment.

FIG. 5 is a cross-sectional view illustrating another example of a non-display area of the display device of FIG. 2, according to an embodiment.

FIG. 6 is a cross-sectional view illustrating another example of a non-display area of the display device of FIG. 2, according to an embodiment.

FIG. 7 is a cross-sectional view illustrating a method of manufacturing a color filter unit included in the display device of FIG. 2, according to an embodiment.

FIG. 8 is a cross-sectional view illustrating a method of manufacturing a color filter unit included in the display device of FIG. 2, according to an embodiment.

FIG. 9 is a cross-sectional view illustrating a method of manufacturing a color filter unit included in the display device of FIG. 2, according to an embodiment.

FIG. 10 is a cross-sectional view illustrating a method of manufacturing a color filter unit included in the display device of FIG. 2, according to an embodiment.

FIG. 11 is a cross-sectional view illustrating a method of manufacturing a color filter unit included in the display device of FIG. 2, according to an embodiment.

FIG. 12 is a cross-sectional view illustrating a method of manufacturing a color filter unit included in the display device of FIG. 2, according to an embodiment.

FIG. 13 is a cross-sectional view illustrating a display device, according to an embodiment.

FIG. 14 is a cross-sectional view illustrating an example of a non-display area of the display device of FIG. 13, according to an embodiment.

FIG. 15 is a cross-sectional view illustrating another example of a non-display area of the display device of FIG. 13, according to an embodiment.

FIG. 16 is a cross-sectional view illustrating another example of a non-display area of the display device of FIG. 13, according to an embodiment.

FIG. 17 is a cross-sectional view illustrating another example of a non-display area of the display device of FIG. 13, according to an embodiment.

FIG. 18 is a block diagram illustrating an electronic device according to embodiments.

FIG. 19 is a diagram illustrating an example in which the electronic device of FIG. 18 is implemented as a smart phone.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” may include all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

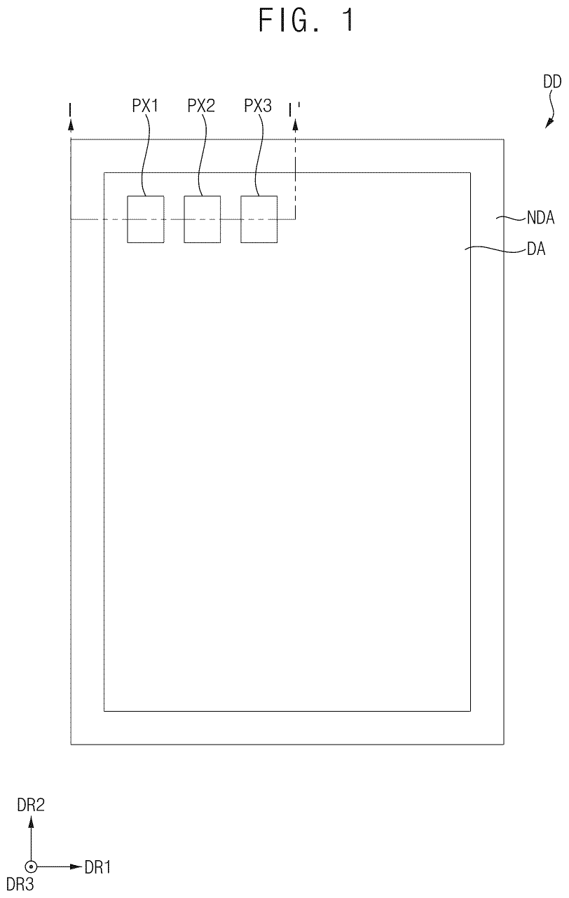

FIG. 1 is a plan view illustrating a display device, according to an embodiment.

In an embodiment and referring to FIG. 1, a display device DD may include a display area DA and a non-display area NDA. The display area DA may be defined as an area emitting light. In addition, components for transmitting a signal to the display area DA may be disposed in the non-display area NDA.

In an embodiment, a plurality of pixel areas may be disposed in the display area DA. For example, a first pixel area PX1, a second pixel area PX2, and a third pixel area PX3 may be disposed in the display area DA.

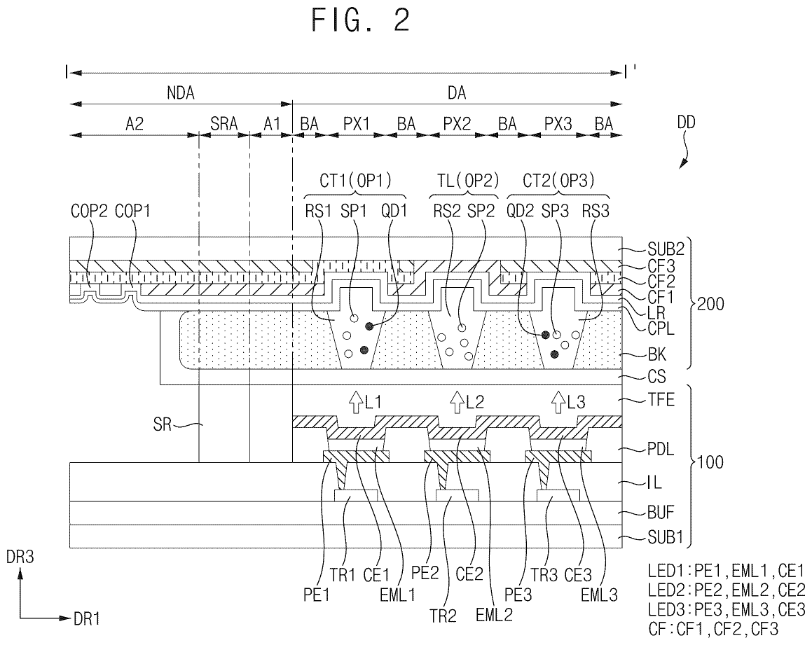

In an embodiment, the first pixel area PX1 may be an area in which light emitted from a first light emitting element (e.g., a first light emitting element LED1 of FIG. 2) is emitted to an outside of the display device DD. In addition, the second pixel area PX2 may be an area in which light emitted from a second light emitting element (e.g., a second light emitting element LED2 of FIG. 2) is emitted to the outside of the display device DD. In addition, the third pixel area PX3 may be an area in which light emitted from the third light emitting element (e.g., a third light emitting element LED3 of FIG. 2) is emitted to the outside of the display device DD.

In an embodiment, the plurality of pixel areas may be repeatedly arranged in a first direction DR1 and a second direction DR2 crossing the first direction DR1 in a plan view. For example, the second pixel area PX2 may be spaced apart from the first pixel area PX1 in the first direction DR1. In addition, the third pixel area PX3 may be spaced apart from the second pixel area PX2 in the first direction DR1.

In an embodiment, the non-display area NDA may be disposed around the display area DA. For example, the non-display area NDA may surround at least a portion of the display area DA. A driver may be disposed in the non-display area NDA. The driver may provide signals or voltages to the plurality of pixel areas. For example, the driver may include a data driver, a gate driver, and the like. The non-display area NDA may not display an image.

FIG. 2 is a cross-sectional view of the display device of FIG. 1 taken along line I-I′, according to an embodiment.

In an embodiment and referring to FIG. 2, the display device DD may include a display unit 100, a color filter unit 200, and a column spacer CS.

In an embodiment, the non-display area NDA may include a first area A1, a sealing area SRA, and a second area A2. The first area A1 may be disposed adjacent to the display area DA in a direction opposite to the first direction DR1. In addition, the sealing area SRA may be disposed adjacent to the first area A1 in a direction opposite to the first direction DR1. In addition, the second area A2 may be disposed adjacent to the sealing area SRA in a direction opposite to the first direction DR1.

In an embodiment, the display unit 100 may include a first base substrate SUB1, a buffer layer BUF, an insulating layer IL, a pixel defining layer PDL, an encapsulation layer TFE, a first pixel electrode PE1, a first light emitting layer EML1, a first common electrode CE1, a second pixel electrode PE2, a second light emitting layer EML2, a second common electrode CE2, a third pixel electrode PE3, a third light emitting layer EML3, a third common electrode CE3, a first transistor TR1, a second transistor TR2, and a third transistor TR3.

In an embodiment, the first transistor TR1 may include a first active pattern, a first gate electrode, a first source electrode, and a first drain electrode. In addition, the second transistor TR2 may include a second active pattern, a second gate electrode, a second source electrode, and a second drain electrode. In addition, the third transistor TR3 may include a third active pattern, a third gate electrode, a third source electrode, and a third drain electrode.

In an embodiment, the first base substrate SUB1 may be continuously disposed over the display area DA and the non-display area NDA. The first base substrate SUB1 may include a transparent material or an opaque material. The first base substrate SUB1 may be formed of a transparent resin substrate. Example of the transparent resin substrate may include a polyimide substrate. In an embodiment, the polyimide substrate may include a first organic layer, a first barrier layer, a second organic layer, and the like.

In another embodiment, the first base substrate SUB1 may include a quartz substrate (e.g. a synthetic quartz substrate, a fluorine-doped quartz substrate), a calcium fluoride substrate, a soda-lime substrate, a non-alkali glass substrate, or the like. These materials may be used alone or in combination with each other.

In an embodiment, the buffer layer BUF may be disposed on the first base substrate SUB1. The buffer layer BUF may be continuously disposed over the display area DA and the non-display area NDA. The buffer layer BUF may prevent metal atoms or impurities from diffusing from the first base substrate SUB1 to the first transistor TR1, the second transistor TR2, and the third transistors TR3. In addition, when a surface of the first base substrate SUB1 is not uniform, the buffer layer BUF may improve flatness of the surface of the first base substrate SUB1.

For example, in an embodiment, the buffer layer BUF may include an inorganic material such as silicon oxide, silicon nitride, silicon oxynitride, or the like. These materials may be used alone or in combination with each other.

In an embodiment, the first transistor TR1, the second transistor TR2, and the third transistor TR3 may be disposed on the buffer layer BUF. For example, in an embodiment, each of the first transistor TR1, the second transistor TR2, and the third transistor TR3 may include polycrystalline silicon or a metal oxide semiconductor.

In an embodiment, the metal oxide semiconductor may include a binary compound (“ABₓ”), a ternary compound (“ABₓC_{y}”), a tetragonal compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, in an embodiment, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

In an embodiment, the insulating layer IL may be disposed on the buffer layer BUF. The insulating layer IL may be continuously disposed over the display area DA and the non-display area NDA. The insulating layer IL may cover each of first transistor TR1, the second transistor TR2, and the third transistor TR3. The insulating layer IL may include at least one inorganic insulating layer and at least one organic insulating layer.

For example, in an embodiment, the inorganic insulating layer may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

In an embodiment, the organic insulating layer may include a photoresist, a polyacryl-based resin, a polyimide-based resin, a polyamide-based resin, a siloxane-based resin, an acryl-based resin, an epoxy-based resin, or the like. These materials may be used alone or in combination with each other.

In an embodiment, the first pixel electrode PE1, the second pixel electrode PE2, and the third pixel electrode PE3 may be disposed on the insulating layer IL. The first pixel electrode PE1 may overlap the first pixel area PX1. In addition, the second pixel electrode PE2 may overlap the second pixel area PX2. In addition, the third pixel electrode PE3 may overlap the third pixel area PX3.

For example, in an embodiment, each of the first pixel electrode PE1, the second pixel electrode PE2, and the third pixel electrode PE3 may include a metal, an alloy, a metal nitride, a conductive metal oxide, a transparent conductive material, or the like. These materials may be used alone or in combination with each other. For example, in an embodiment, each of the first pixel electrode PE1, the second pixel electrode PE2, and the third pixel electrode PE3 may operate as an anode.

In an embodiment, the pixel defining layer PDL may be disposed on the insulating layer IL, the first pixel electrode PE1, the second pixel electrode PE2, and the third pixel electrode PE3. The pixel defining layer PDL may overlap a non-light emitting area BA. The pixel defining layer PDL may cover side portion of the first pixel electrode PE1 and expose an upper surface of the first pixel electrode PE1. In addition, the pixel defining layer PDL may cover a side portion of the second pixel electrode PE2 and expose an upper surface of the second pixel electrode PE2. In addition, the pixel defining layer PDL may cover side portion of the third pixel electrode PE3 and expose an upper surface of the third pixel electrode PE3.

In an embodiment, the pixel defining layer PDL may include an organic material. For example, in an embodiment, the pixel defining layer PDL may include a photoresist, a polyacryl-based resin, a polyimide-based resin, a polyamide-based resin, a siloxane-based resin, an acryl-based resin, an epoxy-based resin, or the like. These materials may be used alone or in combination with each other. In another embodiment, the pixel defining layer PDL may include an inorganic material.

In an embodiment, the first light emitting layer EML1 may be disposed on the first pixel electrode PE1. That is, the first light emitting layer EML1 may overlap the first pixel area PX1. In addition, the second light emitting layer EML2 may be disposed on the second pixel electrode PE2. That is, the second light emitting layer EML2 may overlap the second pixel area PX2. In addition, the third light emitting layer EML3 may be disposed on the third pixel electrode PE3. That is, the third pixel electrode PE3 may overlap the third pixel area PX3.

In an embodiment, holes provided in the first pixel electrode PE1 and electrons provided in the first common electrode CE1 may be combined in the first light emitting layer EML1 to form first excitons. In addition, holes provided in the second pixel electrode PE2 and electrons provided in the second common electrode CE2 may be combined in the second light emitting layer EML2 to form second excitons. In addition, holes provided in the third pixel electrode PE3 and electrons provided in the third common electrode CE3 may be combined in the third light emitting layer EML3 to form third excitons.

In an embodiment, the first light emitting layer EML1 may emit light as the first excitons change from an excited state to a ground state. In addition, the second light emitting layer EML2 may emit light as the second excitons change from an excited state to a ground state. In addition, the third light emitting layer EML3 may emit light as the third excitons change from an excited state to a ground state.

In an embodiment, the first common electrode CE1 may be disposed on the first light emitting layer EML1. In addition, the second common electrode CE2 may be disposed on the second light emitting layer EML2. In addition, the third common electrode CE3 may be disposed on the third light emitting layer EML3. In an embodiment, the first common electrode CE1, the second common electrode CE2, and the third common electrode CE3 may be integrally formed. In another embodiment, the first common electrode CE1 may be separated from the second common electrode CE2. In addition, the second common electrode CE2 may be separated from the third common electrode CE3.

In an embodiment, each of the first common electrode CE1, the second common electrode CE2, and the third common electrode CE3 may include an alloy, a metal nitride, a conductive metal oxide, a transparent conductive material, or the like. These materials may be used alone or in combination with each other. For example, each of the first common electrode CE1, the second common electrode CE2, and the third common electrode CE3 may operate as a cathode.

In an embodiment, a first light emitting element LED1 may include a first pixel electrode PE1, a first light emitting layer EML1, and a first common electrode CE1. In addition, a second light emitting element LED2 may include a second pixel electrode PE2, a second light emitting layer EML2, and a second common electrode CE2. In addition, the third light emitting element LED3 may include a third pixel electrode PE3, a third light emitting layer EML3, and a third common electrode CE3.

In an embodiment, the encapsulation layer TFE may be disposed on the first common electrode CE1, the second common electrode CE2, and the third common electrode CE3. The encapsulation layer TFE may prevent an impurity, moisture, and the like from penetrating into the first light emitting element LED1, the second light emitting element LED2, and the third light emitting element LED3 from an outside.

In an embodiment, the encapsulation layer TFE may include at least one inorganic encapsulation layer and at least one organic encapsulation layer. The inorganic encapsulation layer may include silicon oxide, silicon nitride, silicon oxynitride, or the like. These materials may be used alone or in combination with each other. The organic encapsulation layer may include a cured polymer material such as polyacrylate.

In an embodiment, the color filter unit 200 may include a second base substrate SUB2, a color filter layer CF, a capping layer CPL, a low refractive index layer LR, a bank layer BK, a first color converting layer CT1, a second color converting layer CT2, and a transmitting layer TL.

In an embodiment, the second base substrate SUB2 may include a transparent material. Examples of materials that can be used as the second base substrate SUB2 may include glass, plastic, or the like.

In an embodiment, the color filter layer CF may be disposed under the second base substrate SUB2. The color filter layer CF may include a first color filter CF1, a second color filter CF2, and a third color filter CF3.

In an embodiment, the first color filter CF1 may overlap the second pixel area PX2, the non-light emitting area BA, and the non-display area NDA. In an embodiment, the first color filter CF1 may transmit blue light. However, this invention is not limited thereto, and the first color filter CF1 may transmit light having a wavelength different from a wavelength of blue light. For example, the first color filter CF1 may transmit red light, green light, or the like.

In an embodiment, the first color filter CF1 may define a first cutout portion COP1 and a second cutout portion COP2. Each of the first cutout portion COP1 and the second cutout portion COP2 may partially overlap the second area A2. In addition, the first cutout portion COP1 may be spaced apart from the second cutout portion COP2 in the first direction DR1.

In an embodiment, the second color filter CF2 may be disposed on the first color filter CF1. In addition, the second color filter CF2 may overlap the first pixel area PX1, the non-light emitting area BA, and the non-display area NDA. In an embodiment, the second color filter CF2 may transmit red light. However, this invention is not limited thereto, and the second color filter CF2 may transmit light having a wavelength different from a wavelength of the red light. For example, in an embodiment, the second color filter CF2 may transmit blue light, green light, or the like.

In an embodiment, the third color filter CF3 may be disposed on the second color filter CF2. In addition, the third color filter CF3 may overlap the third pixel area PX3, the non-light emitting area BA, and the non-display area NDA. In an embodiment, the third color filter CF3 may transmit green light. However, this invention is not limited thereto, and the third color filter CF3 may transmit light having a wavelength different a wavelength of the green light. For example, in an embodiment, the third color filter CF3 may transmit blue light, red light, or the like.

In an embodiment, a portion of the first color filter CF1, a portion of the second color filter CF2, and a portion of the third color filter CF3 may overlap in the non-light emitting area BA. Accordingly, color mixing between the first pixel area PX1 and the second pixel area PX2 may be prevented. In addition, color mixing between the second pixel area PX2 and the third pixel area PX3 may be prevented.

In an embodiment, the low refractive index layer LR may be disposed under the color filter layer CF. The low refractive index layer LR may be continuously disposed over the display area DA and the non-display area NDA. The low refractive index layer LR may increase light extraction efficiency, thereby increasing luminance and lifespan of the display device (for example, the display device DD of FIG. 1). In addition, the low refractive index layer LR may fill each of the first cutout portion COP1 and the second cutout portion COP2.

In an embodiment, the low refractive index layer LR may include hollow silica, nano silicate, porogen, or the like. These materials may be used alone or in combination with each other.

In an embodiment, the capping layer CPL may be disposed under the low refractive index layer LR. The capping layer CPL may cover the low refractive index layer LR. That is, the capping layer CPL may be continuously disposed over the display area DA and the non-display area NDA. In an embodiment, the capping layer CPL may include an inorganic material. For example, the capping layer CPL may include silicon oxide, silicon nitride, or the like. These materials may be used alone or in combination with each other.

In an embodiment, the bank layer BK may be disposed under the capping layer CPL. The bank layer BK may overlap the display area DA. In addition, the bank layer BK may overlap the first area Al and the sealing area SRA. In an embodiment, the bank layer BK may partially overlap the second area A2. In another embodiment, the bank layer BK may not overlap the second area A2.

In an embodiment, the bank layer BK may define a first opening OP1. The first opening OP1 may overlap the first pixel area PX1. In addition, the bank layer BK may define a second opening OP2. The second opening OP2 may overlap the second pixel area PX2. In addition, the bank layer BK may define a third opening OP3. The third opening OP3 may overlap the third pixel area PX3.

In an embodiment, the bank layer BK may include an organic material. For example, the bank layer BK may include an acrylic resin, an epoxy resin, a phenol resin, a polyamide resin, a polyimide resin, or the like. These materials may be used alone or in combination with each other.

In another embodiment, the bank layer BK may include an inorganic material. For example, the bank layer BK may include silicon nitride, silicon oxide, or the like. These materials may be used alone or in combination with each other.

In an embodiment, the first color converting layer CT1 may fill the first opening OP1. That is, the first color converting layer CT1 may overlap the first pixel area PX1. In an embodiment, the first color converting layer CT1 may include a first resin part RS1, a first wavelength converting particle QD1, and a first scattering body SP1.

In an embodiment, the first resin part RS1 may include an epoxy resin, an acrylic resin, a phenol resin, a melamine resin, a cardo resin, an imide resin, or the like. These materials may be used alone or in combination with each other.

In an embodiment, the first scattering body SP1 may increase an optical path by scattering a first incident light L1 without substantially converting a wavelength of the first incident light L1 incident on the first color converting layer CT1. In an embodiment, the first scattering body SP1 may include a metal oxide or an organic material. In an embodiment, the first scattering body SP1 may include titanium dioxide (“TiO₂”).

In an embodiment, the first wavelength converting particle QD1 may include a quantum dot. The quantum dot may absorb the first incident light L1 to emit light having a wavelength different from the wavelength of the first incident light L1. In an embodiment, the first wavelength converting particle QD1 may absorb the first incident light L1 to emit red light. However, this invention is not limited thereto. For example, the first wavelength converting particle QD1 may absorb the first incident light L1 to emit blue light.

In an embodiment, the transmitting layer TL may fill the second opening OP2. That is, the transmitting layer TL may overlap the second pixel area PX2. In an embodiment, the transmitting layer TL may include a second resin part RS2 and a second scattering body SP2.

In an embodiment, the second resin part RS2 and the first resin part RS1 may include substantially the same material. In addition, the second scattering body SP2 and the first scattering body SP1 may include substantially the same material.

In an embodiment, the second scattering body SP2 may increase an optical path by scattering a second incident light L2 without substantially converting a wavelength of the second incident light L2 incident on the transmitting layer TL.

In an embodiment, the second color converting layer CT2 may fill the third opening OP3. That is, the second color converting layer CT2 may overlap the third pixel area PX3. In an embodiment, the second color converting layer CT2 may include a third resin part RS3, a third scattering body SP3, and a second wavelength converting particle QD2.

In an embodiment, the third resin part RS3 and the first resin part RS1 may include substantially the same material. In addition, the third scattering body SP3 and the first scattering body SP1 may include substantially the same material. In addition, the second wavelength converting particle QD2 and the first wavelength converting particle QD1 may include substantially the same material.

In an embodiment, the third scattering body SP3 may increase an optical path by scattering a third incident light L3 without substantially converting a wavelength of the third incident light L3 incident on the second color converting layer CT2.

In an embodiment, the second wavelength converting particle QD2 may include a quantum dot. The quantum dot may absorb the third incident light L3 and emit light having a wavelength different from the wavelength of the third incident light L3. In an embodiment, the second wavelength converting particle QD2 may absorb the third incident light L3 and emit green light. However, this invention is not limited thereto. For example, the second wavelength converting particle QD2 may absorb the third incident light L3 and emit blue light.

In an embodiment, each of the first incident light L1, the second incident light L2, and the third incident light L3 may be blue light. However, this invention is not limited thereto, and each of the first incident light L1, the second incident light L2, and the third incident light L3 may be light having a wavelength different from a wavelength of the blue light.

In an embodiment, the column spacer CS may be disposed under the bank layer BK. The column spacer CS may overlap the display area DA, the first area A1, and the sealing area SRA. In an embodiment, the column spacer CS may partially overlap the second area A2. In addition, the column spacer CS may cover a side surface of the bank layer BK. In another embodiment, the column spacer CS may not overlap the second area A2. A gap between the display unit 100 and the color filter unit 200 may be maintained through the column spacer CS.

In an embodiment, the sealing member SR may be disposed between the first base substrate SUB1 and the second base substrate SUB2. For example, in an embodiment, the sealing member SR may be disposed between the column spacer CS and the insulating layer IL. In addition, the sealing member SR may overlap the sealing area SRA. A gap between the first base substrate SUB1 and the second base substrate SUB2 may be maintained in the non-display area NDA through the sealing member SR.

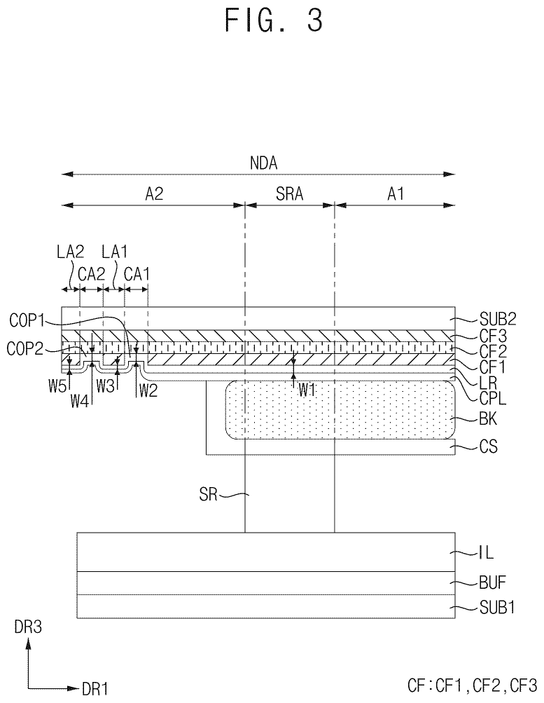

FIG. 3 is a cross-sectional view illustrating an example of a non-display area of the display device of FIG. 2, according to an embodiment.

In an embodiment and referring to FIGS. 2 and 3, the second area A2 may include a first cutout area CA1, a first intermediate area LA1, a second cutout area CA2, and a second intermediate area LA2. The first cutout area CA1 may overlap the first cutout portion COP1. In addition, the second cutout area CA2 may overlap the second cutout portion COP2.

In an embodiment, the first intermediate area LA1 may be disposed between the first cutout area CA1 and the second cutout area CA2. In addition, the second intermediate area LA2 may be disposed adjacent to the second cutout area CA2 in a direction opposite to the first direction DR1. That is, the second intermediate area LA2 may be spaced apart from the first intermediate area LA1 in a direction opposite to the first direction DR1.

In an embodiment, a thickness of the low refractive index layer LR may be constant over the first portion of the second area A2, the sealing area SRA, and the first area A1. The first portion of the second area A2 may be disposed between the sealing area SRA and the first cutout area CA1. For example, in an embodiment, the low refractive index layer LR may have a first thickness W1 in the first portion of the second area A2, the sealing area SRA, and the first area A1.

In an embodiment, the first thickness W1 of the low refractive layer LR may be smaller than a second thickness W2 of the low refractive layer LR overlapping the first cutout area CA1. In addition, the first thickness W1 of the low refractive layer LR may be smaller than a fourth thickness W4 of the low refractive layer LR overlapping the second cutout area CA2.

In an embodiment, the second thickness W2 of the low refractive layer LR and the fourth thickness W4 of the low refractive index layer LR may be substantially the same. In another embodiment, the second thickness W2 of the low refractive layer LR and the fourth thickness W4 of the low refractive layer LR may be different.

In an embodiment, a third thickness W3 of the low refractive index layer LR overlapping the first intermediate area LA1 may be less than the first thickness W1 of the low refractive index layer LR. In addition, a fifth thickness W5 of the low refractive index layer LR overlapping the second intermediate area LA2 may be less than the first thickness W1 of the low refractive index layer LR.

As mentioned above, the low refractive index layer LR may include hollow silica, nano silicate, porogen, or the like. That is, the low refractive index layer LR may include a porous material. Accordingly, moisture, oxygen, and the like may penetrate into the low refractive index layer LR. Specifically, the moisture, the oxygen, and the like may penetrate into the low refractive index layer LR in the non-display area NDA. The moisture and the oxygen penetrating into the low refractive index layer LR in the non-display area NDA may reach the display area DA along the low refractive index layer LR. In this case, a dark spot, a lift of a bank layer BK phenomenon, and the like may occur.

As mentioned above, in an embodiment, the third thickness W3 of the low refractive index layer LR may be less than the first thickness W1 of the low refractive index layer LR. In addition, the fifth thickness W5 of the low refractive index layer LR may be less than the first thickness W1 of the low refractive index layer LR. Accordingly, an area of the low refractive index layer LR through which the moisture and the oxygen may penetrate may be minimized. Accordingly, occurrence of a dark spot, a lift of bank layer BK, and the like, may be minimized.

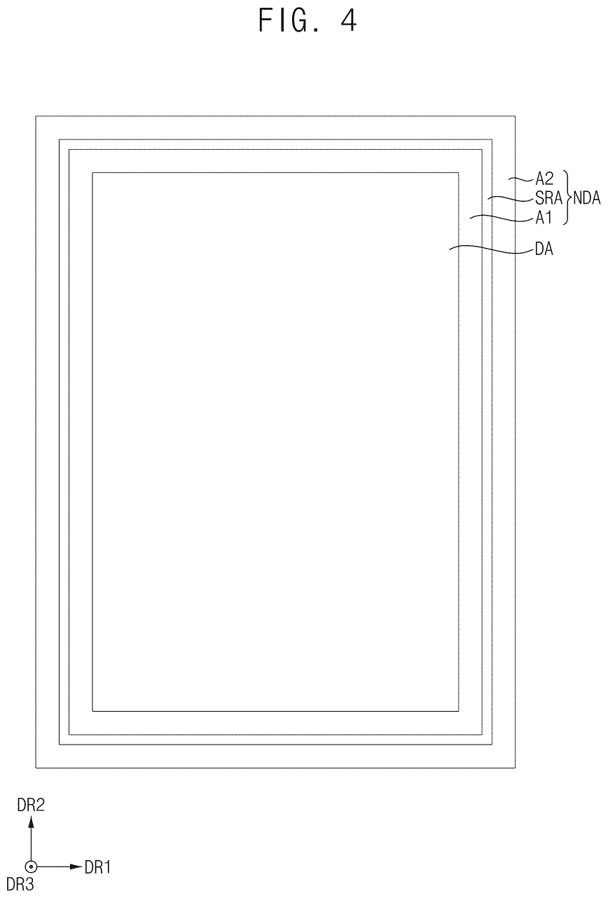

FIG. 4 is a plan view illustrating the display device of FIG. 1, according to an embodiment.

Referring to FIG. 4, in an embodiment, the display area DA may have a rectangular shape having an angled corner in a plan view. However, this invention is not limited thereto. For example, the display area DA may have a rectangular shape having a rounded corner.

In an embodiment, the first area A1 may surround the display area DA. That is, the first area A1 may have a rectangular shape having an empty center portion. In addition, the sealing area SRA may surround the first area A1. That is, the sealing area SRA may have a rectangular shape having an empty central portion. In addition, the second area A2 may surround the sealing area SRA. That is, the second area A2 may have a rectangular shape having an empty central portion.

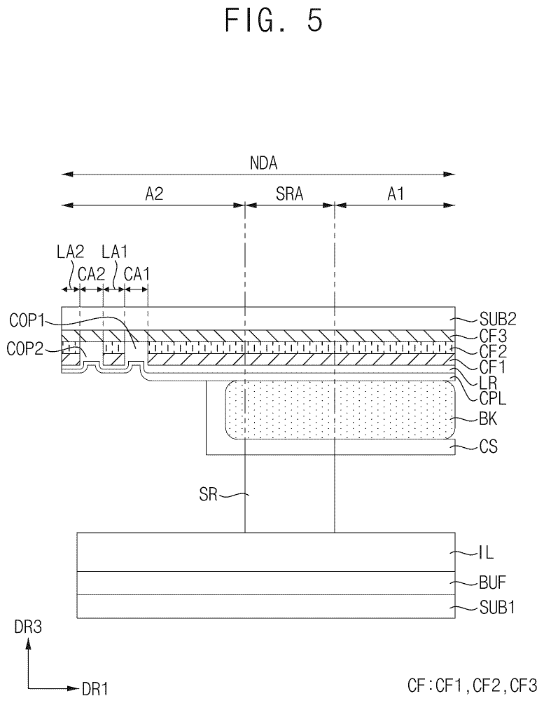

FIG. 5 is a cross-sectional view illustrating another example of a non-display area of the display device of FIG. 2, according to an embodiment.

In an embodiment and referring to FIG. 5, the first color filter CF1 and the second color filter CF2 may define a first cutout portion COP1. That is, the first cutout portion COP1 may be a portion where a first portion of the first color filter CF1 and a first portion of the second color filter CF2 are removed. The first portion of the first color filter CF1 and the first portion of the second color filter CF2 may overlap each other.

In addition, in an embodiment, the first color filter CF1 and the second color filter CF2 may define a second cutout portion COP2. That is, the second cutout portion COP2 may be a portion where a second portion of the first color filter CF1 and a second portion of the second color filter CF2 are removed. The second portion of the first color filter CF1 and the second portion of the second color filter CF2 may overlap each other.

In an embodiment, the non-display area NDA described with reference to FIG. 5 may be substantially the same as the non-display area NDA described with reference to FIG. 3, except for the configurations of the first cutout portion COP1 and the second cutout portion COP2.

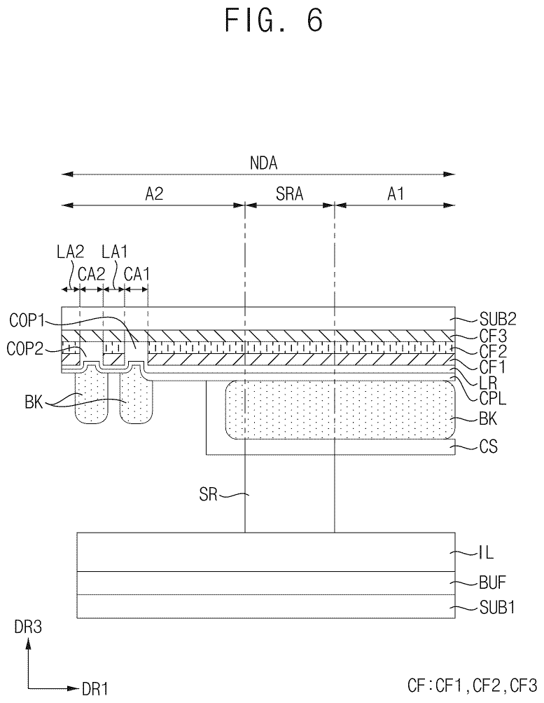

FIG. 6 is a cross-sectional view illustrating another example of a non-display area of the display device of FIG. 2, according to an embodiment.

Referring to FIG. 6, in an embodiment, the bank layer BK may also be disposed in a portion overlapping the first cutout area CA1. In addition, the bank layer BK may also be disposed in a portion overlapping the second cutout area CA2. Accordingly, a color of light incident from the outside of the display device (e.g., the display device DD of FIG. 2) and reflected in the second area A2 may be adjusted.

In an embodiment, the non-display area NDA described with reference to FIG. 6 may be substantially the same as the non-display area NDA described with reference to FIG. 5 except for the configuration of the bank layer BK.

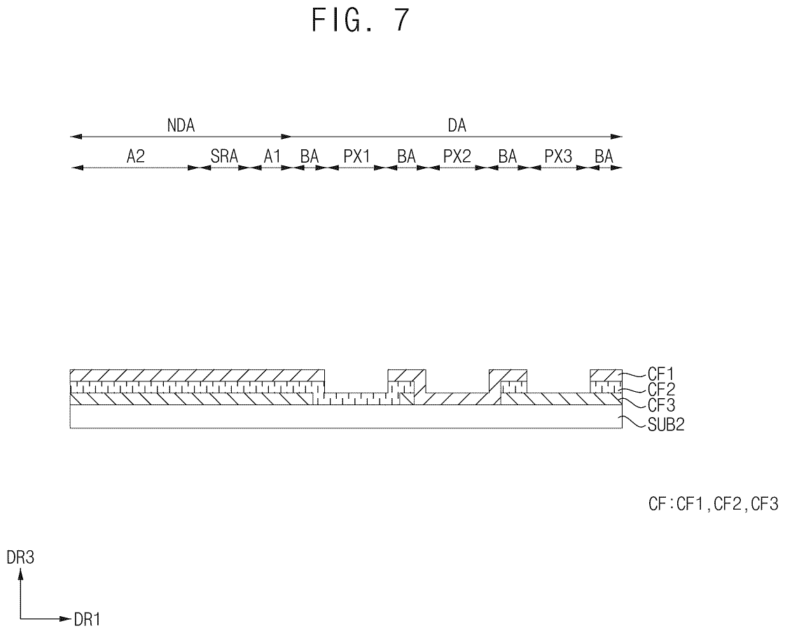

FIGS. 7, 8, 9, 10, 11, and 12 are cross-sectional views illustrating a method of manufacturing a color filter unit included in the display device of FIG. 2, according to an embodiment.

In an embodiment and referring to FIG. 7, the color filter layer CF may be formed on the second base substrate SUB2. The first color filter CF1 may be formed to overlap the second pixel area PX2 and the non-light emitting area BA. In addition, the second color filter CF2 may be formed to overlap the first pixel area PX1 and the non-light emitting area BA. In addition, the third color filter CF3 may be formed to overlap the third pixel area PX3 and the non-light emitting area BA.

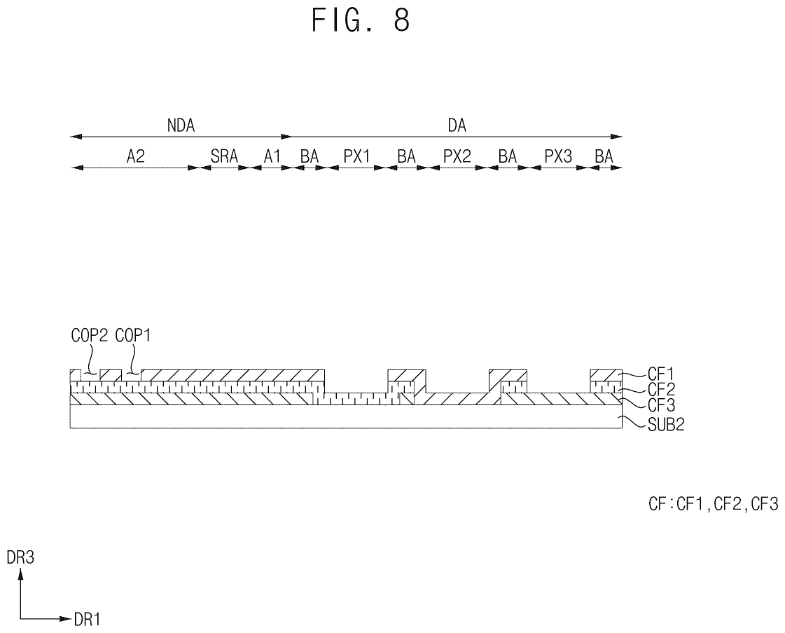

In an embodiment and referring to FIG. 8, the first cutout portion COP1 and the second cutout portion COP2 may be formed in the first color filter CF1. Each of the first cutout portion COP1 and the second cutout portion COP2 may be formed to partially overlap the second area A2. The first cutout portion COP1 may be formed to be spaced apart from the second cutout portion COP2 in the first direction DR1.

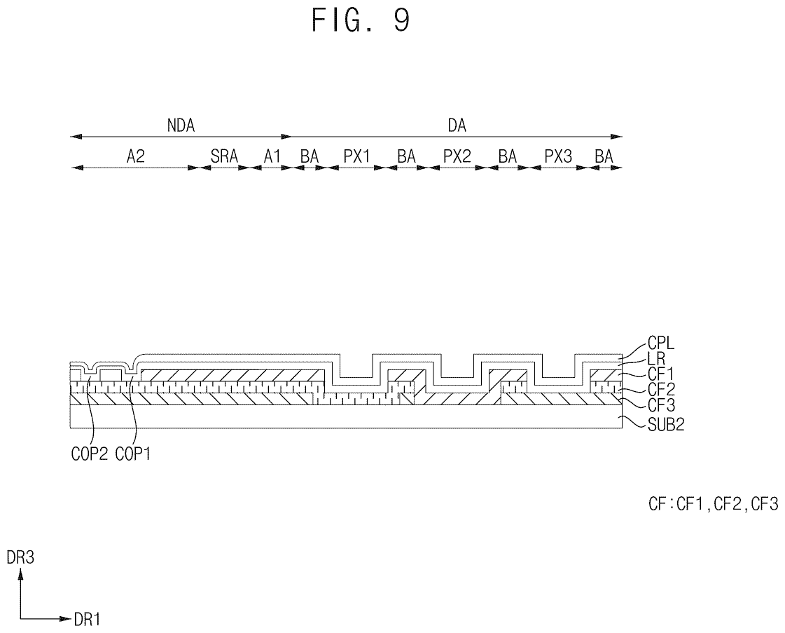

In an embodiment and referring to FIG. 9, the low refractive index layer LR may be

formed on the color filter layer CF. The low refractive index layer LR may be formed to fill each of the first cutout portion COP1 and the second cutout portion COP2. The low refractive index layer LR may include hollow silica, nano silicate, porogen, or the like. These materials may be used alone or in combination with each other.

In an embodiment, the capping layer CPL may be formed on the low refractive index layer LR. That is, the capping layer CPL may be formed to cover the low refractive index layer LR. In an embodiment, the capping layer CPL may include an inorganic material. For example, in an embodiment, the capping layer CPL may include silicon oxide, silicon nitride, or the like. These materials may be used alone or in combination with each other.

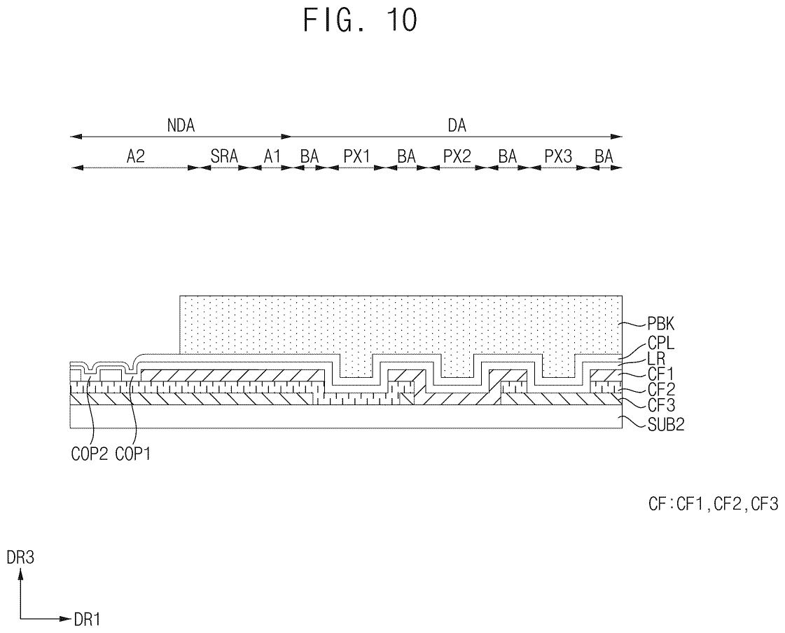

In an embodiment and referring to FIG. 10, a preliminary bank layer PBK may be formed on the capping layer CPL. In an embodiment, the preliminary bank layer PBK may include an organic material. For example, in an embodiment, the preliminary bank layer PBK may include an acrylic resin, an epoxy resin, a phenol resin, a polyamide resin, a polyimide resin, or the like. These materials may be used alone or in combination with each other.

In another embodiment, the preliminary bank layer PBK may include an inorganic material. For example, in an embodiment, the preliminary bank layer PBK may include silicon nitride, silicon oxide, or the like. These materials may be used alone or in combination with each other.

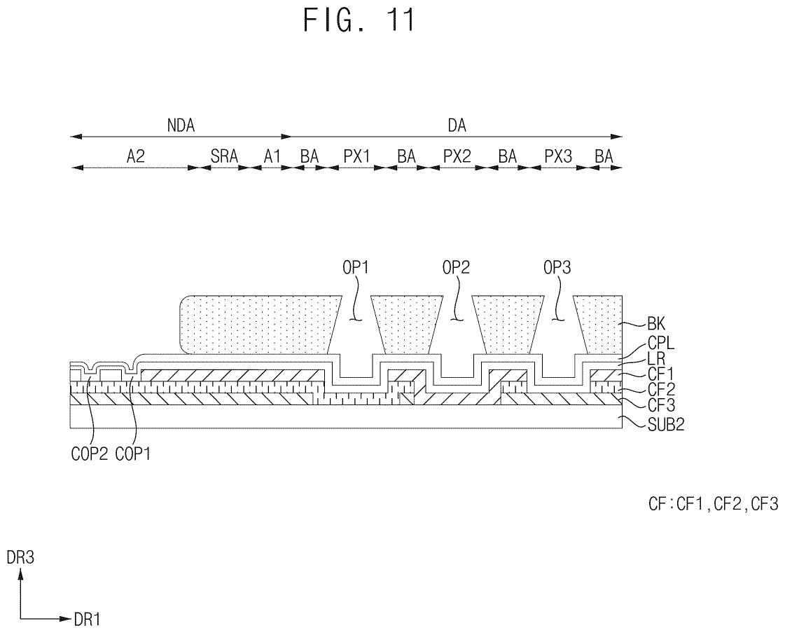

In an embodiment and referring to FIGS. 10 and 11, the first opening OP1, the second opening OP2, and the third opening OP3 may be formed in the preliminary bank layer PBK. Accordingly, a bank layer BK may be formed. The first opening OP1 may be formed to overlap the first pixel area PX1. In addition, the second opening OP2 may be formed to overlap the second pixel area PX2. In addition, the third opening OP3 may be formed to overlap the third pixel area PX3.

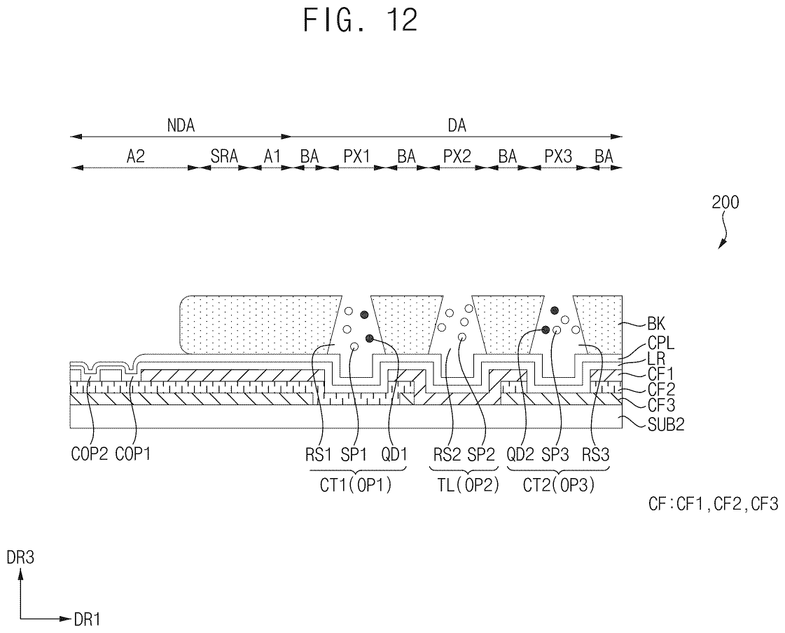

In an embodiment and referring to FIG. 12, the first color converting layer CT1 may be formed in the first opening OP1. The first color converting layer CT1 may be formed on the capping layer CPL. The first color converting layer CT1 may include a first resin part RS1, a first scattering body SP1, and a first wavelength converting particle QD1.

In an embodiment, the transmitting layer TL may be formed in the second opening OP2. The transmitting layer TL may be formed on the capping layer CPL. The transmitting layer TL may include a second resin part RS2 and a second scattering body SP2.

In an embodiment, the second color converting layer CT2 may be formed inside the third opening OP3. The second color converting layer CT2 may be formed on the capping layer CPL. The second color converting layer CT2 may include a third resin part RS3, a third scattering body SP3, and a second wavelength converting particle QD2.

In an embodiment, the color filter unit 200 manufactured according to FIGS. 7, 8, 9, 10, 11, and 12 may be bonded to the display unit 100 of FIG. 2 to form the display device DD of FIG. 2.

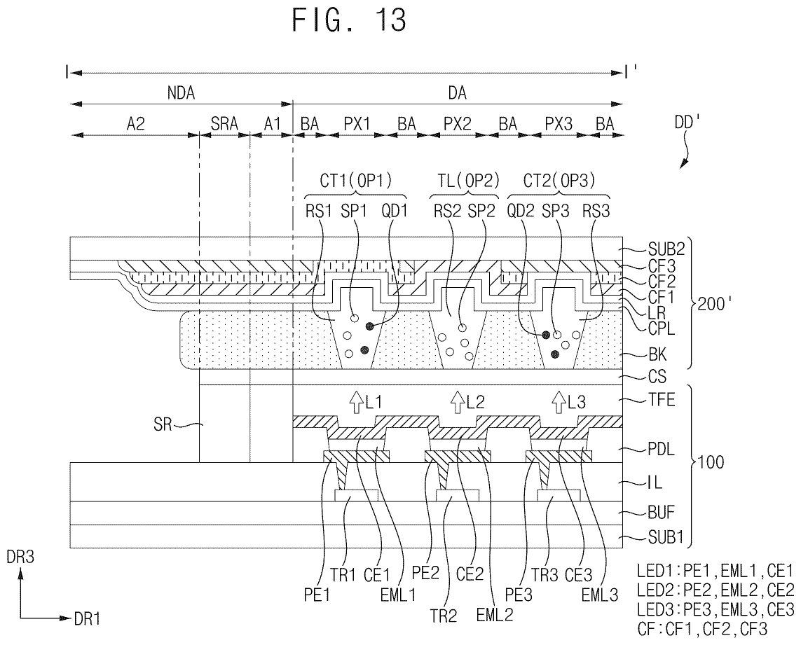

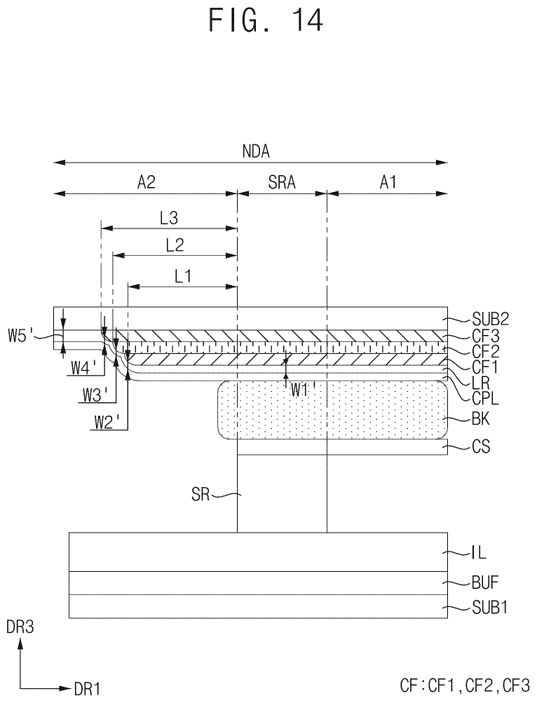

FIG. 13 is a cross-sectional view illustrating a display device, according to another embodiment. FIG. 14 is a cross-sectional view illustrating an example of a non-display area of the display device of FIG. 13, according to an embodiment.

In describing the display device DD′ of FIG. 13, the same reference numerals are assigned to substantially the same configuration as the display device DD of FIG. 2, and a detailed description thereof may be omitted.

Referring to FIGS. 13 and 14, the display device DD′, according to another embodiment, may include a display unit 100, a color filter unit 200′, and a column spacer CS.

In an embodiment, a color filter layer CF may be disposed under the second base substrate SUB2. The color filter layer CF may include a first color filter CF1, a second color filter CF2, and a third color filter CF3.

In an embodiment, the third color filter CF3 may be disposed under the second base substrate SUB2. The third color filter CF3 may overlap the first area A1 and the sealing area SRA. In addition, the third color filter CF3 may partially overlap the second area A2.

In an embodiment, the second color filter CF2 may be disposed under the third color filter CF3. The second color filter CF2 may overlap the first area Al and the sealing area SRA. In addition, the second color filter CF2 may partially overlap the second area A2.

In an embodiment, the first color filter CF1 may be disposed under the second color filter CF2. The first color filter CF1 may overlap the first area A1 and the sealing area SRA. In addition, the first color filter CF1 may partially overlap the second area A2.

In an embodiment, a distance L3 between an end of the third color filter CF3 and the sealing area SRA may be greater than a distance L2 between an end of the second color filter CF2 and the sealing area SRA. Each of the end of the third color filter CF3 and the end of the second color filter CF2 may partially overlap the second area A2.

In addition, in an embodiment, the distance L2 between the end of the second color filter CF2 and the sealing area SRA may be greater than a distance L1 between an end of the first color filter CF1 and the sealing area SRA. The end of the first color filter CF1 may partially overlap the second area A2.

In an embodiment, a low refractive index layer LR may be disposed under the color filter layer CF. The low refractive index layer LR may be continuously disposed over the display area DA and the non-display area NDA.

In an embodiment, the low refractive index layer LR may have a first thickness W1′ in a portion of the second area A2, the first area A1, and the sealing area SRA. In addition, the low refractive index layer LR may have a second thickness W2′ in a portion overlapping the end of the first color filter CF1. In addition, the low refractive index layer LR may have a third thickness W3′ in a portion overlapping the end of the second color filter CF2. In addition, the low refractive index layer LR may have a fourth thickness W4′ in a portion overlapping the end of the third color filter CF3.

In an embodiment, the second thickness W2′ may be less than the first thickness W1″. In addition, the third thickness W3′ may be less than the first thickness W1′. In addition, the fourth thickness W4′may be less than the first thickness W1′. Accordingly, an area of the low refractive index layer LR through which moisture and oxygen may penetrate may be minimized. Therefore, occurrence of a dark spot, a lift of bank layer BK, and the like may be minimized.

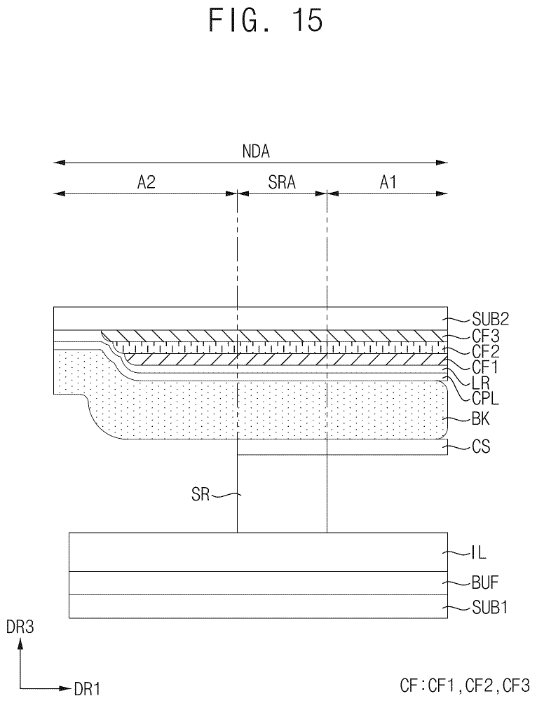

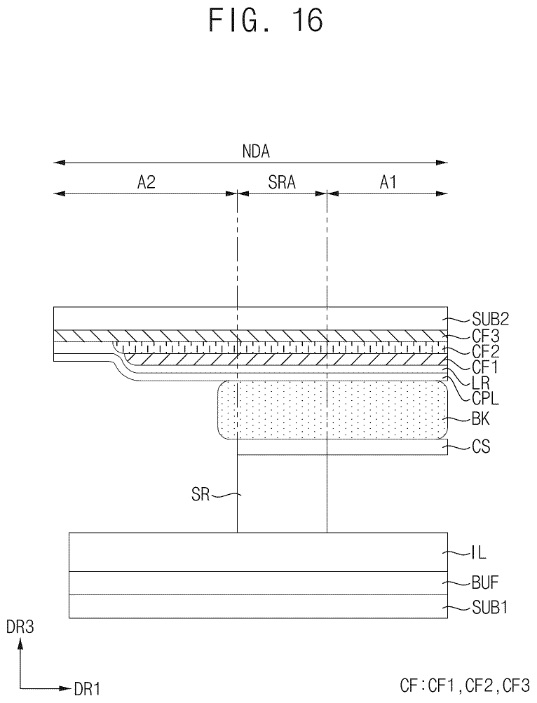

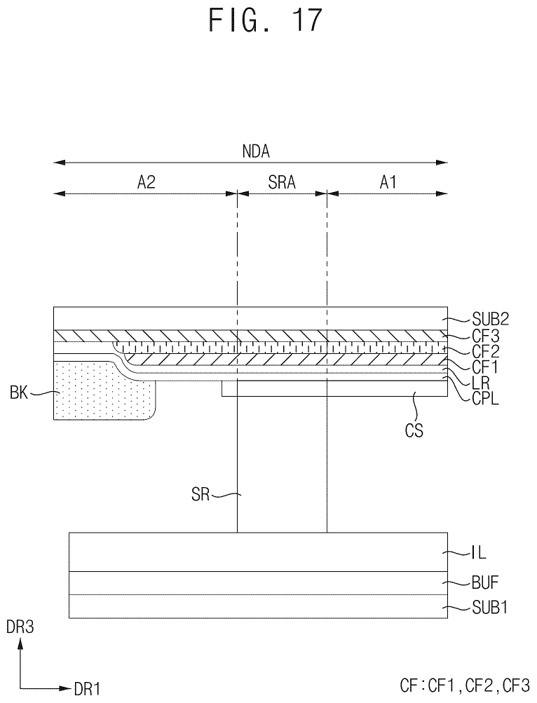

FIG. 15 is a cross-sectional view illustrating another example of a non-display area of the display device of FIG. 13, according to an embodiment. FIG. 16 is a cross-sectional view illustrating another example of a non-display area of the display device of FIG. 13, according to an embodiment. FIG. 17 is a cross-sectional view illustrating another example of a non-display area of the display device of FIG. 13, according to an embodiment.

Referring to FIG. 15, in another embodiment, the bank layer BK may entirely overlap the non-display area NDA. That is, the bank layer BK may overlap the first area A1, the sealing area SRA, and the second area A2.

Referring to FIG. 16, in another embodiment, the third color filter CF3 may entirely overlap the non-display area NDA. That is, the third color filter CF3 may overlap the first area A1, the sealing area SRA, and the second area A2.

Referring to FIG. 17, in another embodiment, the bank layer BK may not overlap the sealing area SRA and the first area A1. The bank layer BK may partially overlap the second area A2. For example, the bank layer BK may be spaced apart from the sealing area SRA in a plan view. In addition, the bank layer BK may overlap the end of the first color filter CF1, the end of the second color filter CF2, and the end of the third color filter CF3. In this case, the column spacer CS may be directly disposed under the capping layer CPL in the first area A1 and the sealing area SRA. Accordingly, a color of light incident from the outside of the display device (for example, the display device DD′ of FIG. 13) and reflected in the second area A2 may be adjusted.

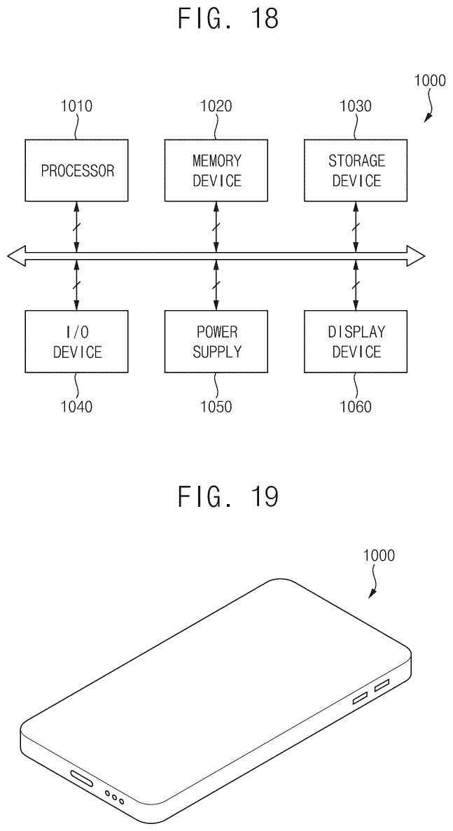

FIG. 18 is a block diagram illustrating an electronic device according to embodiments. FIG. 19 is a diagram illustrating an example in which the electronic device of FIG. 18 is implemented as a smart phone.

Referring to FIGS. 18 and 19, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 19, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The present invention can be applied to various display devices. For example, the present invention is applicable to various display devices such as display devices for vehicles, ships and aircraft, portable communication devices, display devices for exhibition or information transmission, medical display devices, and the like.

The foregoing is illustrative of embodiments of the invention and is not to be construed as limiting thereof. Although a few embodiments have been described, those skilled in the art will readily appreciate that many modifications are possible in the invention without materially departing from the novel teachings and advantages of the present invention. Accordingly, all such modifications are intended to be included within the scope of the present invention. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention. Moreover, the embodiments or parts of the embodiments may be combined in whole or in part without departing from the scope of the invention.

What is claimed is:

1. A display device comprising:
a base substrate including a display area, a first area disposed adjacent to the display area, a sealing area disposed adjacent to the first area, and a second area disposed adjacent to the sealing area;
a second base substrate facing the first base substrate;
a first light emitting element disposed on the first base substrate and partially overlapping the display area;
a second light emitting element disposed on the first base substrate, partially overlapping the display area, and spaced apart from the first light emitting element;
a sealing member disposed between the first base substrate and the second base substrate and overlapping the sealing area;
a color filter layer disposed between the second base substrate and the sealing member, wherein the color filter layer includes a first color filter, a second color filter, and a third color filter, and defines a first cutout portion partially overlapping the second area; and
a low refractive index layer disposed under the color filter layer and filling the first cutout portion.

2. The display device of claim 1, wherein the second color filter is disposed on the first color filter, the third color filter is disposed on the second color filter, and the first cutout portion is a portion from which the first color filter is removed.

3. The display device of claim 2, wherein the first cutout portion is a portion from which both the first color filter and the second color filter are removed.

4. The display device of claim 3, wherein the color filter layer further defines a second cutout portion spaced apart from the first cutout portion and partially overlapping the second area.

5. The display device of claim 4, wherein the second cutout portion is a portion from which the first color filter is removed.

6. The display device of claim 5, wherein the second cutout portion is a portion from which both the first color filter and the second color filter are removed.

7. The display device of claim 4, wherein the low refractive index layer fills the second cutout portion.

8. The display device of claim 4, wherein the second area includes:
a first cutout area overlapping the first cutout portion;
a second cutout area overlapping the second cutout portion;
a first intermediate area disposed between the first cutout area and the second cutout area; and
a second intermediate area disposed adjacent to the second cutout area and spaced apart from the first intermediate area.

9. The display device of claim 8, wherein a thickness of the low refractive index layer overlapping the sealing area is greater than a thickness of the low refractive index layer overlapping the first intermediate area.

10. The display device of claim 9, wherein the thickness of the low refractive index layer overlapping the sealing area is smaller than a thickness of the low refractive index layer overlapping the first cutout area.

11. The display device of claim 8, wherein a thickness of the low refractive index layer overlapping the sealing area is greater than a thickness of the low refractive index layer overlapping the second intermediate area.

12. The display device of claim 1, further comprising:
a bank layer disposed between the color filter layer and the first base substrate, and defining a first opening overlapping the first light emitting element and a second opening overlapping the second light emitting element.

13. The display device of claim 12, further comprising:
a color converting layer filling the first opening and including a first scattering body and a first wavelength converting particle.

14. The display device of claim 13, further comprising:
the transmitting layer filling the second opening and including the second scattering body.

15. The display device of claim 12, wherein the bank layer overlaps the first area and the sealing area, and partially overlaps the second area.

16. A display device comprising:
a base substrate including a display area, a first area disposed adjacent to the display area, a sealing area disposed adjacent to the first area, and a second area disposed adjacent to the sealing area;
a second base substrate facing the first base substrate;
a first light emitting element disposed on the first base substrate and partially overlapping the display area;
a second light emitting element disposed on the first base substrate, partially overlapping the display area, and spaced apart from the first light emitting element;
a sealing member disposed between the first base substrate and the second base substrate and overlapping the sealing area;
a color filter layer disposed between the second base substrate and the sealing member, partially overlapping the second area, overlapping the sealing area and the first area, and including a first color filter, a second color filter disposed on the first filter, and a third color filter disposed on the second color filter; and
a low refractive index layer disposed under the color filter layer,
wherein a distance between an end of the second color filter and the sealing area is greater than a distance between an end of the first color filter and the sealing area.

17. The display device of claim 16, wherein a distance between an end of the third color filter and the sealing area is greater than the distance between the end of the second color filter and the sealing area.

18. The display device of claim 17, wherein the third color filter completely overlaps the second area.

19. The display device of claim 17, wherein a thickness of the low refractive index layer overlapping the sealing area is greater than a thickness of each of the low refractive index layer overlapping the end of the first color filter, the low refractive index layer overlapping the end of the second color filter, and the low refractive index layer overlapping the end of the third color filter.

20. The display device of claim 17, further comprising:
a bank layer disposed between the color filter layer and the sealing member and overlapping the first area, the second area, and the sealing area.

21. An electronic device comprising:
a base substrate including a display area, a first area disposed adjacent to the display area, a sealing area disposed adjacent to the first area, and a second area disposed adjacent to the sealing area;
a second base substrate facing the first base substrate;
a first light emitting element disposed on the first base substrate and partially overlapping the display area;
a second light emitting element disposed on the first base substrate, partially overlapping the display area, and spaced apart from the first light emitting element;
a sealing member disposed between the first base substrate and the second base substrate and overlapping the sealing area;
a color filter layer disposed between the second base substrate and the sealing member, wherein the color filter layer includes a first color filter, a second color filter, and a third color filter, and defines a first cutout portion partially overlapping the second area;
a low refractive index layer disposed under the color filter layer and filling the first cutout portion; and
a memory device configured to store data.
